(19) United States
(12) Patent Application Publication
(10) Pub. No.: US 2010/0282960 A1
(43) Pub. Date: Nov. 11, 2010

(54) COMBINED IMAGING AND TRACE-DETECTION INSPECTION SYSTEM AND METHOD

(76) Inventor: Keith A. Clark, La Mesa, CA (US)

Correspondence Address: PATRICK W. RASCHE (22697);ARMSTRONG TEASDALE LLP, 7700 Forsyth Boulevard, Suite 1800, St. Louis, MO, 63105, US

(21) Appl. No.: 11/964,490

(22) Filed: Dec. 26, 2007

(51) Int. Cl. G01T 1/00; H01J 49/00; G01J 5/02; G01J 1/42; G01R 33/44

(52) U.S. Cl. 250/282; 250/340; 250/395; 324/307; 250/336.1; 250/281; 250/338.1

(57) ABSTRACT

Systems and methods for imaging and chemically identifying contraband are described. In one aspect, a method is provided for locating and identifying contraband on a subject. The method includes scanning the subject using a plurality of imaging sensors to collect radiometric data, collecting chemical data from chemical vapors and particles located on and/or near the subject using a trace-detection sensor, and fusing the collected radiometric data and the collected chemical data to generate at least one of a location of the contraband and a probability of a chemical composition of the contraband.

### FIELD OF THE INVENTION

The embodiments described herein relate generally to passenger inspection systems and, more particularly, to passenger inspection systems capable of imaging and chemical identification of contraband, and method for operating the same.

### BACKGROUND OF THE INVENTION

Since the events of Sep. 11, 2001, the Department of Homeland Security has increased security dramatically in U.S. airports. Such security efforts include screening passengers and carry-on bags and luggage for contraband including explosive materials.

At least some known security scanning systems employ X-ray transmission technology to localize potential threats. For example, systems employing X-ray scanners are used widely in airports around the world on passengers to detect weapons and/or explosives that pose a threat to aviation safety. These systems employ an X-ray source and opposing detectors that detect X-ray radiation that passes through a person with the person positioned between the source and detectors.

In addition, at least some known security scanning systems employ trace detection systems to identify the chemical composition of potential threats. For example, systems employing chemical detectors may be used to detect contraband, such as explosives, that also may pose a threat to aviation security. Such systems may employ a detector to detect a presence of molecules of interest from an airflow that carries such molecules from the person's skin.

At least some known scanning systems are capable of detecting contraband, such as weapons and explosives. However, there is a need for a system that is able to localize potential contraband and to identify contraband by its chemical composition.

### BRIEF DESCRIPTION OF THE INVENTION

In one aspect, a method is provided for locating and identifying contraband on a subject. The method includes scanning the subject using a plurality of imaging sensors to collect radiometric data, collecting chemical data from chemical vapors and particles located on or near the subject using a trace-detection sensor, and fusing the collected data and the collected chemical data to generate at least one of a location and a probability of a chemical composition of the contraband.

In another aspect, a security portal is provided for locating and identifying contraband on a subject. The security portal includes a plurality of imaging sensors for collecting radiometric data of the subject, a trace-sampling sensor for collecting chemical data from the subject, and a computer system configured to be operatively coupled to the imaging sensors and the trace-sampling sensor, wherein the computer system is further configured to fuse the radiometric data and the chemical data to obtain at least one of a location and a composition of the contraband.

In another aspect, a system is provided for locating and identifying contraband on a subject. The system includes a gantry having a cylindrical form factor, a plurality of imaging sensors configured to be mechanically moved within the gantry to collect radiometric data of the subject, a trace-sampling sensor coupled to the gantry and configured to collect chemical data from the subject, and a computer system electrically coupled to the imaging sensors and the trace-sampling sensor. The computer system is configured to fuse the radiometric data and the chemical data to determine at least one of a location and a composition of the contraband.

### BRIEF DESCRIPTION OF THE DRAWINGS

FIGS. 1, 2, and 3 show exemplary embodiments of the systems and methods described herein.

FIG. 1 is an exterior view of a security portal;

FIG. 2 is a block diagram of a detection system suitable for use with the security portal shown in FIG. 1; and

FIG. 3 is a flowchart illustrating a method for locating and identifying contraband on and/or near a subject using the detection system shown in FIG. 2.

### DETAILED DESCRIPTION OF THE INVENTION

The embodiments described herein provide a system and method for processing the output of a multi-sensor portal that includes an imaging component and a trace detection component. In one embodiment, an array of radiometric imaging sensors collect radiometric data from a subject to generate a radiometric image. A trace-sampling sensor collects chemical data from vapors and/or particles on and/or near the subject to determine a chemical composition of materials that are held by the subject, such as weapons and/or explosives. The radiometric image data and the collected chemical data are combined by a computer system to create a single image for display to a user. Moreover, the embodiments described herein provide technical effects such as, but not limited to, collecting radiometric data and chemical data, and fusing the data using a computer system to create a single image for display to a user including a location of contraband on or near a subject, and a likely chemical composition of the contraband.

At least one embodiment of the present invention is described below in reference to its application in connection with and operation of a system for inspecting passengers for contraband in their possession. Such contraband may be concealed in, for example, a pocket or between layers of clothing. As used herein, the terms “on a subject” or “near a subject” describe possession of contraband or suspected contraband by the subject. However, it should be apparent to those skilled in the art and guided by the teachings herein provided that the invention is likewise applicable to any suitable system for scanning people including, without limitation, visitors to secured locations and/or employees at sensitive locations. Moreover, the invention is likewise applicable to any system for scanning passengers that are transported by water, land, and/or air.

Moreover, although embodiments of the present invention are described below in reference to application in connection with and operation of a system incorporating a scanning system for inspecting passengers, it should be apparent to those skilled in the art and guided by the teachings herein provided that any suitable imaging system may be used in alternative embodiments. Further, it should be apparent to those skilled in the art and guided by the teachings herein provided that any trace-detection system may be used to enable the functionality of the scanning system described herein.

The embodiments described herein include systems and methods for detecting contraband using both imaging sensors and a trace-detection sensor. One example of an imaging technology that may be used in conjunction with the systems and methods described herein is known as Extremely High Frequency (EHF). Extremely High Frequency is the highest radio frequency band and includes the range of frequencies from approximately 30 gigahertz (GHz) to approximately 300 GHz. This frequency band has a wavelength of between approximately 1 millimeter (mm) and approximately 10 mm. As such, this frequency band is typically called “millimeter band” or “millimeter wave,” and is sometimes abbreviated as “MMW” or “mmWave.” The millimeter wave frequency band may be used to remotely sense an object using passive sensors that detect natural radiation emitted or reflected by the object. The quality of mmWave sensing depends in part on a radiometric resolution, which typically refers to a number of different intensities of radiation that a sensor is able to distinguish. The radiometric resolution may have a value represented by between 8 bits and 14 bits, which correspond to approximately 256 levels of gray scale and up to 16,384 shades of color. In one embodiment of the systems and methods described herein, mmWave imaging is accomplished using a passive radiometric sensor array and imaging system that collects natural thermal emission of each object within a security portal. The imaging system generates an image by detecting and analyzing radiant electromagnetic energy that is emitted by each object within an imaging space, such as a security portal. Within the mmWave range, the amount of emitted energy varies greatly between metallic objects and non-metallic objects, such that metallic objects appear “cold” as compared to non-metallic objects. Thus, the imaging system analyzes the detected energy emissions and generates an image that highlights the detected energy emissions differences.

Another example of an imaging technology that may be used in conjunction with the systems and methods described herein is known as terahertz imaging. Electromagnetic waves that are transmitted at terahertz frequencies may also be called “terahertz radiation” or “terahertz waves.” Such waves typically lie in the region of the electromagnetic spectrum between approximately 300 GHz and 3 terahertz (THz), and typically have a wavelength between approximately 1 mm and 100 micrometers (μm). Terahertz waves are able to penetrate coverings such as fabrics and plastics, enabling its use in security screening to uncover contraband, such as concealed weapons, on a person. Moreover, many materials of interest, such as plastic explosives, possess unique spectral fingerprints that lie in the terahertz range, offering the possibility to combine spectral identification with imaging. In addition, terahertz radiation is readily absorbed by water. It can therefore be used to distinguish between materials with varying water content. The varying absorption characteristics of terahertz radiation between different materials may be used to create images.

Still another example of an imaging technology that may be used in conjunction with the systems and methods described herein is known as nuclear quadrupole resonance (NQR) imaging. Unlike nuclear magnetic resonance (NMR), which is typically used to detect atoms with nuclei having a nuclear quadrupole moment, NQR imaging is accomplished in an environment that does not have a static magnetic field. A nucleus with more than one unpaired nuclear particle, whether protons or neutrons, will have a quadrupolar charge distribution. The interaction of this quadrupole with an electric field gradient supplied by a non-uniform distribution of electron density causes an NQR effect. As such, the NQR imaging is sensitive to the nature of the particle bonding around the nucleus. NQR spectra for use in imaging may only be measured for solids. An imaging system that uses NQR, as described herein, includes a radio frequency (RF) source, a coil to produce a magnetic excitation field that interacts with the atomic quadrupoles, and a detector circuit or array which monitors for an NQR response being emitted by an object suspected of being contraband.

One example of a trace-detection technology that may be used in conjunction with the systems and methods described herein is known as ion mobility spectroscopy (IMS), which is a method of detecting and identifying small concentrations of chemicals based upon a differential migration of gaseous ions through an electric field. An IMS system measures the speed with which an ion moves through a given atmosphere having a uniform electric field. The molecules of the sample are typically ionized. Ionization may be accomplished by corona discharge, atmospheric pressure photoionization (APPI), electrospray ionization (ESI), or a radioactive source. A typical ion mobility spectrometer includes an ion molecule reaction chamber, an ionization source associated with the ion reaction chamber, an ion drift chamber, an ion/molecule injection shutter, such as a Bradbury-Nielsen-Shutter, placed between the ion reaction chamber and the ion drift chamber, and an ion collector, such as a Faraday plate. A carrier gas, such as air or nitrogen, transports the subject gases or vapors into the ion mobility spectrometer. An ionization source charges the carrier gas and the subject gases or vapors. The charged gas molecules are accelerated by an electrostatic field gradient maintained between a counter electrode and the Faraday plate, which causes the molecules to travel toward the injection shutter interface of the ion drift chamber. By monitoring the amount of time between the introduction of the charged molecules into the drift region and the arrival of the charged molecules at a collector plate, it is possible to identify the different ionic species. The quantity of ions collected as a function of drift time records as a current, which is analyzed by a computer system to determine the likely composition of materials within the portal.

Another example of a trace-detection technology that may be used in conjunction with the systems and methods described herein is known as nuclear resonance fluorescence (NRF). Nuclear resonance fluorescence is the process of causing resonant excitation of nuclear states using a beam of electromagnetic radiation, and the proceeding decay of the nuclear states. Nuclear resonance fluorescence is able to non-intrusively interrogate a region space and measure the isotopic content of the material in the space for the elements within the space. Material is exposed to a continuous energy distribution of photons and one or more detectors detect the photons emitted from the material having an particular energy distribution.

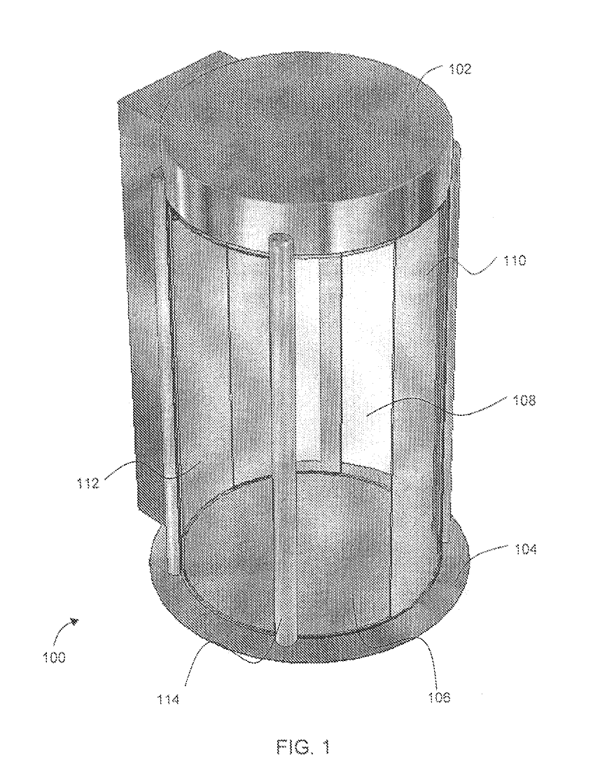

FIG. 1 is an exterior view of a security portal 100 in accordance with the system and method described herein. Portal 100 defines a cylindrical form factor and includes an enclosure top 102 and an enclosure bottom 104. A standing surface 106 is coupled to enclosure bottom 104. Alternatively, standing surface 106 and enclosure bottom 104 may be formed from a unitary piece. Portal 100 also includes one or more entrances 108 through which a subject, such as a passenger, enters portal 100. Moreover, portal 100 also includes one or more doors 110 that are slidably coupled to enclosure top 102 and enclosure bottom 104 to facilitate enclosing portal 100 by covering entrance 108. In an alternative embodiment, doors 110 may be hingedly coupled to portal 100. Portal 100 also includes one or more fixedly coupled enclosure coverings 112 to further facilitate enclosing portal 100. In addition, portal 100 includes a plurality of columnar supports 114 coupled to enclosure 102 and enclosure bottom 104 to facilitate supporting enclosure top 102.

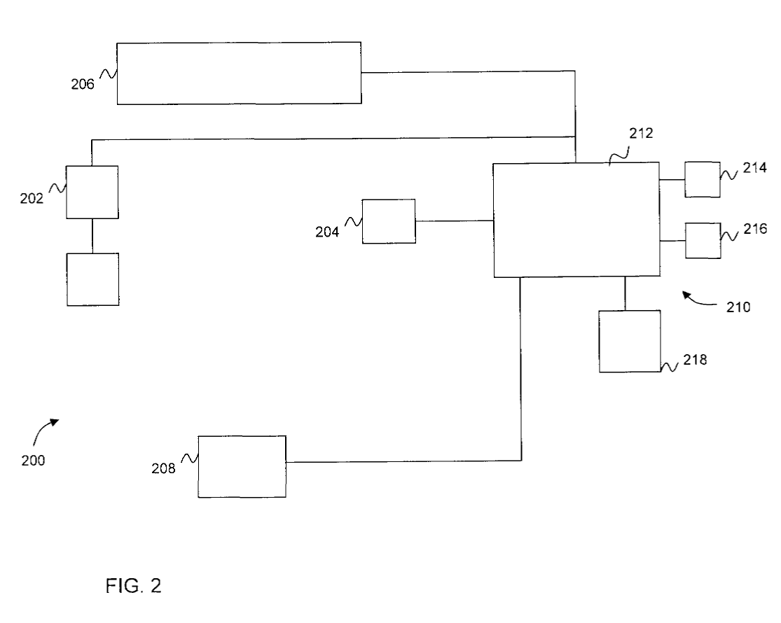

FIG. 2 is a block diagram of a detection system 200 that may be used with portal 100 (shown in FIG. 1). In the exemplary embodiment, system 200 includes a plurality of imaging sensors 202. Imaging sensors 202 are moveably coupled to portal 100 such that imaging sensors 202 may be moved in a vertical direction. Alternative embodiments may move imaging sensors 202 in a horizontal direction or may rotate imaging sensors 202 about a subject. In one embodiment, imaging sensors 202 are passive sensors configured to operate in the mmWave frequency band of the electromagnetic spectrum by detecting natural radiation emitted or reflected by the subject and any materials on and/or near the subject. In an alternative embodiment, imaging sensors 202 are configured to operate in a terahertz band of the electromagnetic spectrum. More specifically, imaging sensors 202 are configured to operate in a region of the electromagnetic spectrum with a lower boundary of approximately 1 THz. In a further alternative embodiment, imaging sensors 202 are nuclear quadrupole resonance (NQR) sensors. In this alternative embodiment, system 200 also includes a radio frequency source 204 that emits RF waves directed at the subject. The RF waves that pass through the subject are collected by the NQR sensors.

In the exemplary embodiment, system 200 also includes a trace-detection sensor 206 coupled to enclosure top 102 (shown in FIG. 1). System 200 also includes an emitter 208 coupled to enclosure bottom 104 (shown in FIG. 1). In alternative embodiments, trace-detection sensor 206 and/or emitter 208 may be positioned within enclosure top 102 and enclosure bottom 104, respectively, such that trace-detection sensor 206 and/or emitter 208 are not visible to the subject upon entry into portal 100. In one embodiment, trace-detection sensor 206 is an ion mobility spectroscopy (IMS) sensor and emitter 208 is a carrier gas emitter that emits a carrier gas, such as nitrogen or air, for transporting vapors and/or particles on and/or near the subject to the IMS sensor. In an alternative embodiment, trace-detection sensor 206 is a nuclear resonance fluoroscopy sensor and emitter 208 is a photon emitter 208 that focuses a photon beam on the subject within portal 100.

Moreover, in the exemplary embodiment, system 200 includes a computer system 210 that analyzes and fuses data collected by imaging sensors 202 and trace-detection sensor 206 to generate an image including any suspected contraband in the subject's possession and a chemical identification of the contraband. Computer system 210 includes a processor 212 that may include any programmable system including systems using microcontrollers, reduced instruction set circuits (RISC), application specific integrated circuits (ASIC), programmable logic circuits (PLC), and any other circuit or processor capable of executing the functions described herein. The above examples are exemplary only and are thus not intended to limit in any way the definition and/or meaning of the term processor. Moreover, computer system 210 includes one or more input devices such as a mouse 214 and/or a keyboard 216. Computer system 210 also includes a display 218 for viewing the image generated by computer system 210.

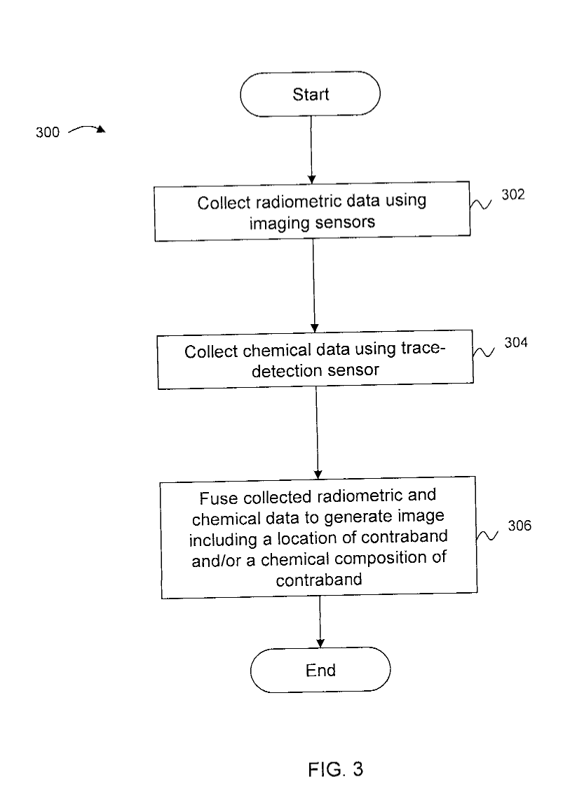

FIG. 3 is a flowchart illustrating a method 300 for locating and identifying contraband on and/or near a subject. In the exemplary embodiment, after a subject, such as a passenger, enters security portal 100 (shown in FIG. 1), radiometric data is collected 302 using imaging sensors 202 (shown in FIG. 2). More specifically, imaging sensors 202 are mechanically moved in a first direction, such as substantially vertically in relation to portal 100. Alternative embodiments may move imaging sensors 202 in a substantially horizontal direction or may rotate imaging sensors 202 about the subject. In one embodiment, imaging sensors 202 are configured to operate in the mmWave frequency band of the electromagnetic spectrum. The mmWave sensors detect and collect radiation emitted or reflected by the subject and any materials on and/or near the subject, and generate one or more signals representative of the detected radiation and/or the detected material. The mmWave sensors then transmit the signals to computer system 210 (shown in FIG. 2) for analysis. Processor 212 (shown in FIG. 2) generates a radiometric image from the signals received from the mmWave sensors.

In an alternative embodiment, imaging sensors 202 are configured to operate in a region of the electromagnetic spectrum with a lower boundary of approximately 1 THz. The terahertz sensors detect and collect radiation emitted or reflected by the subject and any materials on and/or near the subject, and generate one or more signals representative of the detected radiation. The terahertz sensors then transmit the signals to computer system 210 for analysis. Processor 212 generates a radiometric image from the signals received from the terahertz sensors.

In a further alternative embodiment, imaging sensors 202 are NQR sensors. Radio frequency source 204 (shown in FIG. 2) emits RF waves at a predetermined frequency, and the RF waves pass through the subject. The NQR sensors detect and collect the RF waves after the waves pass through the subject. The NQR sensors generate one or more signals representative of the detected RF waves and transmit the signals to computer system 210 for analysis. Processor 212 generates a radiometric image from the signals received from the NQR sensors.

In the exemplary embodiment, chemical data is collected 304 using trace-detection sensor 206. More specifically, in one embodiment, trace-detection sensor 206 is an ion mobility spectroscopy (IMS) sensor and emitter 208 is a carrier gas emitter. The carrier gas emitter emits a carrier gas, such as air or nitrogen, that transports vapors and/or particles on and/or near the subject to the IMS sensor. An ionization source within the IMS sensor or, alternatively, within enclosure top 102 (shown in FIG. 1), charges the carrier gas and subject vapors and/or particles. The charged gases and particles are then accelerated by an electrostatic field gradient that is created and maintained between an electrode and a Faraday plate. The IMS sensor measures the amount of time between the introduction of the charged gases and particles into a drift region and the arrival of the charged gases and particles at a collector plate. The IMS sensor generates a signal representative of the measurement and transmits the signal to computer system 210 for analysis. Processor 212 determines a probable chemical composition of the space within portal 100 from the signal received from the IMS sensor. More specifically, processor 212 determines a probable chemical composition of materials on and/or near the subject using the signal received from the IMS sensor.

In an alternative embodiment, trace-detection sensor 206 is a nuclear resonance fluoroscopy (NRF) sensor and emitter 208 is a photon emitter. The emitter irradiates the subject within portal 100 with high-energy photons. The radiation causes the subject, as well as materials on and/or near the subject, to emit gamma-rays which are then detected by the NRF sensor. The NRF sensor generates a signal representative of the detected gamma-rays and transmits the signal to computer system 210 for analysis. Processor 212 determines a probable chemical composition of materials within portal 100 from the signal received from the NRF sensor. More specifically, processor 212 determines a probable chemical composition of materials on and/or near the subject using the signal received from the NRF sensor.

In the exemplary embodiment, processor 212 fuses 306 the collected radiometric data and the collected chemical data to generate an image that includes a location of contraband and/or a chemical composition of contraband. The image includes the radiometric data with the chemical data as an overlay. More specifically, the radiometric image generated by processor 212 includes radiometric metadata and the chemical data transmitted to computer system 210 includes chemical metadata. Processor 212 combines the radiometric metadata and the chemical metadata into a single dataset, resulting in a single image showing the radiometric image and having a chemical composition overlay as detected by trace-detection sensor 206. More specifically, the chemical composition overlay uses colors associated with particular chemical compositions and/or elements to identify materials on and/or near the subject having corresponding chemical compositions and/or elements. For example, the final image may include a particular color that represents a particular type of explosive, such that the color is overlaid onto the radiometric image at a location within a jacket worn by a subject currently being scanned within the portal. Both the location and the chemical identification may be determined from the final image, and the subject may be subjected to a physical search based on the contents of the final image and/or from other information gathered from the final image.

In summary, in one embodiment, a method for locating and identifying contraband on a subject is provided. The method includes scanning a subject using a plurality of radiometric imaging sensors and generating a signal representative of the detected radiometric data. The signal is then transmitted by the imaging sensors to a computer system for analysis. In one embodiment, the subject is scanned using a plurality of radiometric imaging sensors configured to operate in a millimeter wave (mmWave) region of the electromagnetic spectrum. In an alternative embodiment, the subject is scanned using a plurality of radiometric imaging sensors configured to operate in a region of the electromagnetic spectrum having a lower frequency of at least 1 terahertz (THz). In a further alternative embodiment, radio frequency (RF) waves are emitted and pass through the subject. The RF waves are detected by a plurality of nuclear quadrupole resonance (NQR) sensors.

The method also includes scanning the subject using a trace-detection sensor and an emitter. The trace-detection sensor generates a signal representative of the detected chemical composition within vapors and/or particles on and/or near the subject, and transmits the signal to the computer system for analysis. In one embodiment, the trace-detection sensor is an ion mobility spectroscopy (IMS) sensor and the emitter is a carrier gas emitter. The carrier gas emitter emits a gas that transports vapors and/or particles within the portal to the IMS sensor. In an alternative embodiment, the trace-detection sensor is a nuclear resonance fluoroscopy (NRF) sensor and the emitter is a photon emitter. The photon emitter irradiates the subject within the portal with high-energy photons causing gamma-rays to be emitted by the subject and any materials on and/or near the subject.

The method also includes fusing the radiometric data and the chemical data to form a final image showing the location of suspected contraband and a probable chemical composition of the suspected contraband. Radiometric metadata and chemical metadata are combined into a single dataset and an image is display to a user from the single dataset. The image includes the radiometric image data and a chemical composition overlay identifying a probable chemical composition of suspected contraband.

While the methods and systems described herein have been described in terms of various specific embodiments, those skilled in the art will recognize that the methods and systems described herein may be practiced with modification within the spirit and scope of the appended claims.

What is claimed is:

1. A method for locating and identifying contraband on a subject, said method comprising:
scanning the subject using a plurality of imaging sensors to collect radiometric data;
collecting chemical data from chemical vapors and particles located on or near the subject using a trace-detection sensor; and
fusing the collected radiometric data and the collected chemical data to generate at least one of a location of the contraband and a probability of a chemical composition of the contraband.

2. A method in accordance with claim 1 wherein scanning the subject comprises scanning the subject using a plurality of radiometric imaging sensors configured to operate in a millimeter wave region of an electromagnetic spectrum.

3. A method in accordance with claim 1 wherein scanning the subject comprises scanning the subject using a plurality of radiometric imaging sensors configured to operate in a region of an electromagnetic spectrum having a lower frequency of at least 1 terahertz.

4. A method in accordance with claim 1 wherein scanning the subject comprises scanning the subject using a plurality of nuclear quadrupole resonance sensors.

5. A method in accordance with claim 1 wherein scanning the subject comprises mechanically moving the plurality of imaging sensors in a first direction.

6. A method in accordance with claim 1 wherein collecting chemical data comprises collecting chemical data using an ion mobility spectroscopy sensor.

7. A method in accordance with claim 1 wherein collecting chemical data comprises collecting chemical data using a nuclear resonance fluoroscopy sensor.

8. A method in accordance with claim 1 wherein fusing the radiometric data and the chemical data comprises combining metadata of the radiometric data with metadata of the chemical data to generate a fused image for display to a user, the fused image including a radiometric image and an overlay of chemical data.

9. A security portal for locating and identifying contraband on a subject, said security portal comprising:
a plurality of imaging sensors for collecting radiometric data of the subject;
a trace-sampling sensor for collecting chemical data from the subject; and
a computer system configured to be operatively coupled to said plurality of imaging sensors and said trace-sampling sensor, said computer system further configured to fuse the radiometric data and the chemical data to obtain at least one of a location and a composition of the contraband.

10. A security portal in accordance with claim 9 further comprising a gantry comprising a cylindrical form factor, said plurality of imaging sensors are mechanically moved within said gantry when collecting radiometric data of the subject.

11. A security portal in accordance with claim 9 wherein said plurality of imaging sensors are configured to operate in one of a millimeter wave region of an electromagnetic spectrum and a region of the electromagnetic spectrum having a lower boundary frequency of at least one terahertz.

12. A security portal in accordance with claim 9 wherein said plurality of imaging sensors comprises a plurality of nuclear quadrupole resonance sensors.

13. A security portal in accordance with claim 9 wherein said trace-sampling sensor comprises an ion mobility spectroscopy sensor.

14. A security portal in accordance with claim 9 wherein said trace-sampling sensor comprises a nuclear resonance fluoroscopy sensor.

15. A security portal in accordance with claim 9 wherein said computer system is further configured to combine metadata of the radiometric data with metadata of the chemical data to generate a fused image for display to a user, the fused image including a radiometric image and an overlay of chemical data.

16. A system for locating and identifying contraband on a subject, said system comprising:
a gantry comprising a cylindrical form factor;
a plurality of imaging sensors configured to be mechanically moved within said gantry to collect radiometric data of the subject;
a trace-sampling sensor coupled to said gantry and configured to collect chemical data from the subject; and
a computer system electrically coupled to said plurality of imaging sensors and said trace-sampling sensor, said computer system configured to fuse the radiometric data and the chemical data to determine at least one of a location and a composition of the contraband.

17. A system in accordance with claim 16 wherein said plurality of imaging sensors are configured to operate in one of a millimeter wave region of an electromagnetic spectrum and a region of the electromagnetic spectrum having a lower boundary frequency of at least one terahertz.

18. A system in accordance with claim 16 wherein said plurality of imaging sensors comprises a plurality of nuclear quadrupole resonance sensors.

19. A system in accordance with claim 16 wherein said trace-sampling sensor comprises one of an ion mobility spectroscopy sensor and a nuclear resonance fluoroscopy sensor.

20. A system in accordance with claim 16 wherein said computer system is further configured to combine metadata of the radiometric data with metadata of the chemical data to generate a fused image for display to a user, the fused image including a radiometric image and an overlay of chemical data.
